(19) United States
(12) Patent Application Publication
(10) Pub. No.: US 2014/0283735 A1
(43) Pub. Date: Sep. 25, 2014

(54) METHOD FOR GROWTH OF INGOT

(71) Applicants: Kyoung Seok Min, Seoul (KR); Dong Geun Shin, Seoul (KR)

(72) Inventors: Kyoung Seok Min, Seoul (KR); Dong Geun Shin, Seoul (KR)

(73) Assignee: LG INNOTEK CO., LTD., Seoul (KR)

(21) Appl. No.: 14/235,651

(22) PCT Filed: Jul. 26, 2012
(86) PCT No.: PCT/KR2012/005988

§ 371 Date: Jun. 5, 2014

(30) Foreign Application Priority Data
Jul. 28, 2011 (KR) 10-2011-0075474

(51) Int. Cl. C30B 23/06

(52) U.S. Cl. CPC C30B 23/066
USPC 117/84

(57) ABSTRACT

A method for growing an ingot according to the embodiment includes filling a first powder in a crucible; raising a temperature of the crucible; forming a second powder by grain-growing the first powder; and growing the ingot by sublimating the second powder.

### TECHNICAL FIELD

The disclosure relates to a method for growing an ingot.

### BACKGROUND ART

In general, materials are very important factors to determine the property and the performance of final products in the electric, electronic and mechanical industrial fields

SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC, a seeded growth sublimation scheme has been suggested. In this case, after putting a raw material in a crucible, an SiC single crystal serving as a seed is provided on the raw material. A temperature gradient is formed between the raw material and the seed, so that the raw material in the crucible is dispersed to the seed, and re-crystallized to grow the ingot.

Referring to Korean Unexamined Patent Publication No. 10-2011-0059399, SiC powder is typically used as a raw material to grow such an SiC ingot. When the SiC powder is used as a raw material, the loss of the raw material may be caused due to the dispersion of the SiC powder. Thus, a product yield of the ingot may be decreased, and particles may be attached to a seed so that defects may occur.

### DISCLOSURE OF INVENTION

### Technical Problem

The embodiment can grow a high-quality ingot.

### Solution to Problem

A method for growing an ingot according to the embodiment includes filling a first powder in a crucible; raising a temperature of the crucible; forming a second powder by grain-growing the first powder; and growing the ingot by sublimating the second powder.

### Advantages Effects of Invention

According to the method for growing the ingot of the embodiment, ultrahigh-purity powder may be grain-grown. If ultrahigh-purity powder of 99% or above is used as a raw material, impurities, which are introduced into the ingot grown from the high-purity raw material, may be minimized, so that defect may not occur.

Since the ultrahigh purity may be kept through the grain-growing and the diameter may be enlarged, the scattering and particle problems of the fine powder may be solved. Further, impurities due to the particles may be minimized, so that a high-quality ingot can be grown with a low defect.

### BRIEF DESCRIPTION OF DRAWINGS

FIG. 1 is a flowchart showing a method for growing an ingot according to the embodiment;

FIG. 2 is a graph illustrating the method for growing the ingot according to the embodiment;

FIG. 3 is a graph illustrating the method for growing the ingot according to another embodiment; and

FIGS. 4 to 6 are sectional views illustrating the method for growing the ingot according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or over the other substrate, layer (or film), region, pad, or pattern, or one or more intervening layers may also be present. Such a position of the layer has been described with reference to the drawings.

Since the thickness and size of each layer shown in the drawings may be modified for the purpose of convenience or clarity of description, the size of elements does not utterly reflect an actual size.

Hereinafter, the embodiment will be described with reference to accompanying drawings.

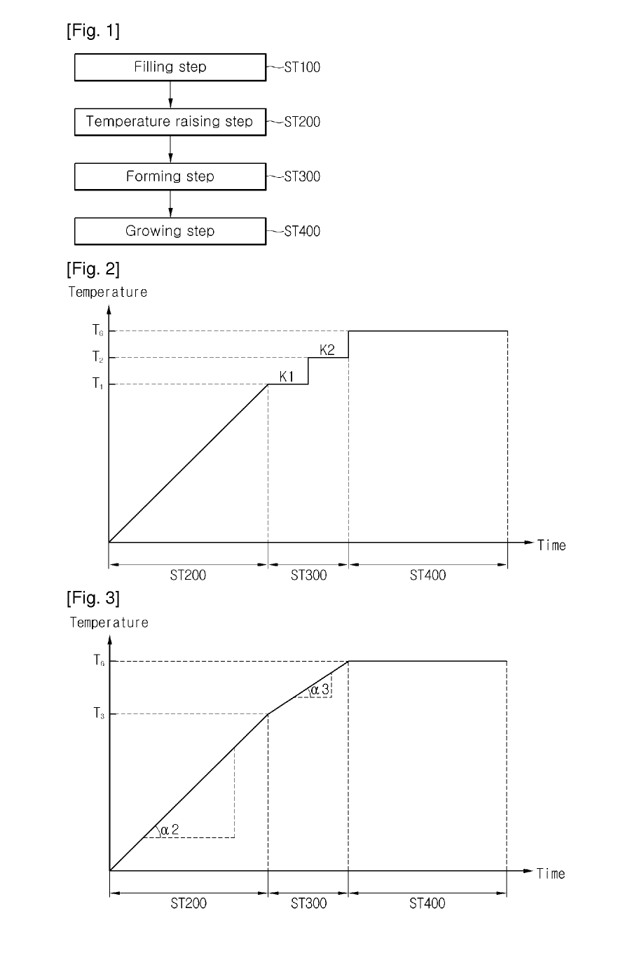

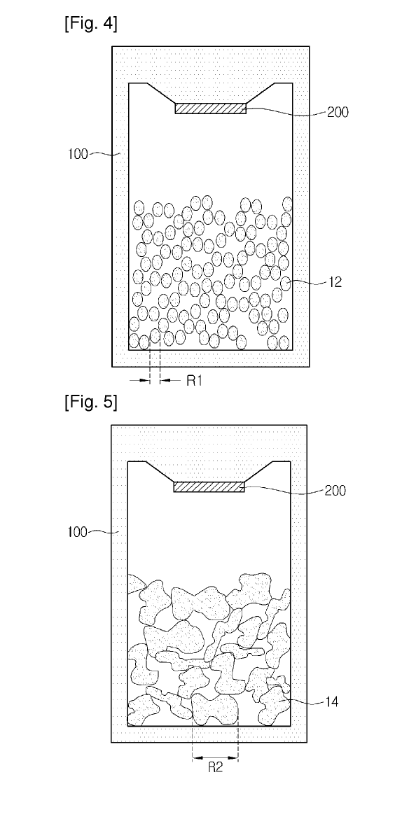

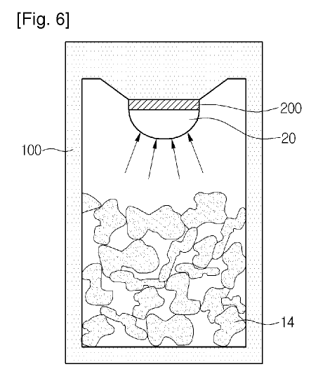

The method for growing the ingot according to the embodiment will be described in detail with reference to FIGS. 1 to 6. FIG. 1 is a flowchart showing a method for growing an ingot according to the embodiment. FIG. 2 is a graph illustrating the method for growing the ingot according to the embodiment. FIG. 3 is a graph illustrating the method for growing the ingot according to another embodiment. FIGS. 4 to 6 are sectional views illustrating the method for growing the ingot according to the embodiment.

Referring to FIG. 1, the method for growing the ingot according to the embodiment includes a filling step ST100, a temperature raising step ST200, a forming step ST300, and a growing step ST400.

Referring to FIG. 4, in the filling step ST100, a first powder 12 may be filled in a crucible 100.

The crucible 100 may have a cylindrical shape such that the crucible 100 can receive the first powder 12.

The crucible 100 may include a material having a melting point which is equal to or higher than the sublimation temperature of silicon carbide.

As one example, the crucible 100 may be formed of graphite.

The first powder 12 may include silicon carbide (SiC) powder. The purity of the silicon carbide powder may be 99.9% or above. In detail, the purity of the silicon carbide powder may be in the range of 99.999% to 99.9999999%.

A scheme for obtaining the high-purity silicon carbide powder includes a carbon-thermal reduction scheme, a direct reaction scheme, a liquid polymer thermal decomposition scheme, and a high-temperature self-propagating combustion synthesis scheme.

According to the above technologies, the silicon carbide is manufactured by mixing a solid-phase silicon source, such as SiO2 or Si, with a carbon source, such as carbon or graphite, and heat-treating the mixture at the temperature in the range of 1350° C. to 2000° C.

Specifically, among the above schemes, the carbon-thermal reduction and direct reaction schemes are typically used for obtaining high-purity silicon carbide particles.

As one example, ultrahigh-purity silicon carbide particles may be obtained through the following procedure. First, a step of forming a silicon carbide raw material mixture by mixing SiO2 powder and a carbon source may be performed. The carbon source may be carbon black or a resin material. Further, the mixing ratio of carbon to silicon may be in the range of 1:1 to 3:1.

Then, the step of obtaining the silicon carbide particle by heat-treating the mixture material in the crucible 100 at the temperature in the range of 1300° C. to 2000° C. for 30 minutes to 7 hours is performed. The crucible 100 may be formed of graphite. The inner space of the crucible 100 may be vacuum or filled with inert gas.

However, the embodiment is not limited to the above, and various methods may be used to obtain the ultrahigh-purity SiC powder.

The purity of the first powder 12 may exert a great influence on the quality of the ingot grown in the crucible 100. When powder having the ultrahigh-purity of 99.9% or above is used as a raw material, impurities introduced into the ingot grown from the high-purity raw material may be diminished, so that defect can be prevented.

The diameter R1 of the first powder 12 may be in the range of 50 nm to 10 μm. That is, the first powder 12 may be ultrahigh-purity fine powder.

Then, in the temperature raising step ST200, the crucible 100 may be heated. Although not shown in drawings, a heat generation induction part may be placed at the outside of the crucible 100 such that the crucible 100 may be heated. The crucible 100 may generate heat by itself using the heat generation induction part. As one example, the heat generation induction part may be a high-frequency induction coil. The crucible 100 may be heated by allowing a high-frequency current to flow through the high-frequency induction coil. That is, the raw material received in the crucible 100 may be heated to a desired temperature.

Then, referring to FIG. 5, in the forming step ST300, the first powder 12 may be grain-grown such that the second powder 14 may be formed.

The forming step ST300 may be performed at an ingot growth temperature or below. In detail, the growing step ST400 may be performed at a growth temperature TG and the step ST300 of forming the second powder 14 may be performed at the growth temperature TG or below. As one example, the step ST300 of forming the second powder 14 may be performed at the temperature in the range of 1800° C. to 2100° C.

Referring to FIG. 2, in the forming step ST300, the temperature may be gradually increased.

In detail, the forming step may include a step of raising the temperature to a first temperature T1, a step K1 of maintaining the first temperature T1, a step of raising the temperature to a second temperature T2 which is higher than the first temperature T1, and a step K2 of maintaining the second temperature T2.

Although only the steps of raising the temperature to the second temperature T2 and maintaining the second temperature T2 are depicted in the drawings, the embodiment is not limited thereto. Thus, the steps of raising the temperature to a third temperature which is higher than the second temperature T2 and maintaining the third temperature T3 may be further included.

However, the embodiment is not limited the above, and referring to FIG. 3, the temperature may be continuously increased in the forming step ST300. The forming step ST300 may be performed at a rate which is slower than the temperature raising rate of the temperature raising step ST200. In detail, the temperature may rise with the gradient of α2 in the temperature raising step ST200, and in the forming step ST300, the temperature may be increased at a temperature raising rate having the gradient of α3 which is smooth than the α2. That is, in the forming step ST300, the grain growth of the first powder 12 may be induced by reducing the rate of raising the temperature from the temperature T3 which is lower than the growth temperature TG to the growth temperature TG.

The second powder 14 which is grain-grown may be formed through the forming step ST300. That is, the first powder 12 which is first filled in the crucible 100 may be grain-grown. Since the first powder 12 is fine particles having the diameter in the range of 50 nm to 10 μm, the first powder 12 may be rapidly grain-grown. That is, the plural particles of the first powder 12 may react to be combined to each other, so that the second powder 14 having a greater diameter than that of the first powder 12 may be formed. Further, a faster and rapider grain growth may be implemented through the gradual temperature rise.

Thus, the ultrahigh-purity may be kept and the grain size may become larger, so that the scattering and particle problems of the fine powder may be solved. Further, impurities due to the particles may be minimized, so that a low-defect and high-quality ingot can be grown.

A diameter R2 of the second powder 14 may be in the range of 100 μm to 600 μm. An average of the diameter R2 of the second powder 14 may be 300 μm.

In the growing step ST400, the ingot 20 may be grown. The growing step ST400 may be performed at the growth temperature TG. In the growing step ST400, the second powder 14 may be sublimated so as to be transferred to the seed 200 in the crucible 100, and the ingot 20 may be grown.

In detail, a temperature gradient may be formed in the crucible 100 such that an upper portion and a low portion of the crucible 100 may have temperatures different from each other. Due to the temperature gradient, the second powder 14 is sublimated and the sublimated silicon carbide gas moves to a surface of the seed 200 having the relatively low temperature. Thus, the silicon carbide gas is grown in the ingot 20 through the re-crystallization.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A method for growing an ingot, the method comprising:
filling a first powder in a crucible;
raising a temperature of the crucible;
forming a second powder by grain-growing the first powder; and
growing the ingot by sublimating the second powder.

2. The method of claim 1, wherein the first powder has purity of 99.9% or above.

3. The method of claim 1, wherein the first powder has purity in a range of 99.999% to 99.9999999%.

4. The method of claim 1, wherein the first powder has a diameter in a range of 50 nm to 10 μm.

5. The method of claim 1, wherein the growing of the second powder is performed at a temperature in a range of 1800 ° C. to 2100 ° C.

6. The method of claim 5, wherein the temperature is gradually increased in the forming of the second powder.

7. The method of claim 5, wherein the forming of the second powder includes:
raising the temperature to a first temperature;
maintaining the first temperature;
raising the temperature to a second temperature which is higher than the first temperature;
maintaining the second temperature.

8. The method of claim 7, wherein the forming of the second powder further
raising the temperature to a third temperature which is higher than the second temperature; and
maintaining the third temperature.

9. The method of claim 5, wherein the temperature is continuously increased in the forming of the second powder.

10. The method of claim 1, wherein the second powder has a diameter in a range of 100 μm to 600 μm.

11. The method of claim 1, wherein the growing of the ingot is performed at a growth temperature, and the growing of the second powder is performed at the growth temperature or below.

12. The method of claim 9, wherein the forming of the second powder is performed at a rate which is lower than a temperature raising rate in the raising of the temperature.
